(19) United States
(12) Patent Application Publication
(10) Pub. No.: US 2023/0411246 A1
(43) Pub. Date: Dec. 21, 2023

(54) SEMICONDUCTOR INTEGRATED CIRCUIT DEVICE

(71) Applicant: Socionext Inc., Kanagawa (JP)

(72) Inventor: Hideyuki KOMURO, Yokohama-shi (JP)

(21) Appl. No.: 18/447,032

(22) Filed: Aug. 9, 2023

Related U.S. Application Data
(63) Continuation of application No. PCT/JP2022/002398, filed on Jan. 24, 2022.

(30) Foreign Application Priority Data
Feb. 15, 2021 (JP) 2021-021737

(51) Int. Cl. H01L 23/48; H01L 27/088; H01L 29/78

(52) U.S. Cl. CPC H01L 23/481; H01L 27/0886; H01L 29/7851

(57) ABSTRACT

A semiconductor integrated circuit device includes a plurality of cells each having a fin FET. A plurality of fins constituting the fin FET extend in the X direction and are placed on virtual grid lines equally spaced in the Y direction. The cells include buried power lines: cells larges in size in the Y direction include buried power lines larger in width. The center position of each of the buried power lines in the Y direction is on a virtual grid line or at a center position between adjacent virtual grid lines.

### CROSS-REFERENCE TO RELATED APPLICATIONS

This is a continuation of International Application No. PCT/JP2022/002398 filed on Jan. 24, 2022, which claims priority to Japanese Patent Application No. 2021-021737 filed on Feb. 15, 2021. The entire disclosures of these applications are incorporated by reference herein.

### BACKGROUND

The present disclosure relates to a semiconductor integrated circuit device provided with standard cells.

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through interconnects, thereby designing an LSI chip.

Also, for higher integration of a semiconductor integrated circuit device, it is proposed to use, for standard cells, buried power rails (BPRs) that are power lines laid in a buried interconnect layer, not power lines laid in a metal interconnect layer formed above transistors as conventionally done.

U.S. Patent Application Publication No. 2019/0080969 (FIG. 1E) discloses a configuration of a block constituted by standard cells, in which buried power rails are used and connected to sources of transistors and further connected to power lines laid in an upper interconnect layer.

Since buried power rails are buried in a substrate, they cannot be formed in regions where the sources, drains, and channels of transistors are present. Buried power rails however need to have a sufficient current supply capability for transistors. Also, in order to prevent manufacturing variations, transistors such as fin field effect transistors (FETs) and nanosheet FETs are restricted in their sizes and placement positions in microfabrication processes in some cases.

An objective of the present disclosure is providing a semiconductor integrated circuit device using buried power lines in which buried power lines having a sufficient line width can be laid without blocking regular placement of fin FETs.

### SUMMARY

According to one mode of the present disclosure, a semiconductor integrated circuit device includes a plurality of standard cells each having a fin field effect transistor (FET), wherein a plurality of fins constituting the fin FET extend in a first direction and placed on ones of virtual grid lines equally spaced in a second direction vertical to the first direction, the plurality of standard cells include a first standard cell and a second standard cell larger in size in the second direction than the first standard cell, the first standard cell includes a first buried power line extending in the first direction, the second standard cell includes a second buried power line extending in the first direction, the second buried power line being larger in size in the second direction than the first buried power line, and a center position of each of the first and second buried power lines in the second direction is on one of the virtual grid lines or at a center position between adjacent ones of the virtual grid lines.

According to the above mode, in a semiconductor integrated circuit device, a plurality of fins constituting a fin FET extend in the first direction and are placed on virtual grid lines equally spaced in the second direction. The first and second standard cells include buried power lines: the second standard cell larger in size in the second direction includes a buried power line larger in size in the second direction. With this, a sufficient current supply capability for fin FETs can be obtained. Also, the center positions of the buried power lines of the first and second standard cells in the second direction are on virtual grid lines or at the center positions between adjacent virtual grid lines. With this, buried power lines having a sufficient line width can be laid without blocking regular placement of fin FETs.

According to the present disclosure, in a semiconductor integrated circuit device using buried power lines, buried power lines having a sufficient line width can be laid without blocking regular placement of fin FETs.

### BRIEF DESCRIPTION OF THE DRAWINGS

FIGS. 1A-1B are plan views showing layout structures of inverter cells constituting a semiconductor integrated circuit device according to an embodiment.

FIGS. 2A-2B are cross-sectional views of the inverter cell shown in FIG. 1A.

FIGS. 3A-3B are plan views showing layout structures of 2-input NAND cells constituting the semiconductor integrated circuit device according to the embodiment.

FIG. 4A is a circuit diagram of an inverter cell, and FIG. 4B is a circuit diagram of a 2-input NAND cell.

FIG. 5 shows a configuration example of circuit blocks of the semiconductor integrated circuit device according to the embodiment.

FIG. 6 is a partial enlarged view of FIG. 5.

FIG. 7 is a plan view showing a layout structure of another inverter cell constituting the semiconductor integrated circuit device according to the embodiment.

### DETAILED DESCRIPTION

An embodiment of the present disclosure will be described hereinafter with reference to the accompanying drawings. In the following embodiment, it is assumed that the semiconductor integrated circuit device includes a plurality of standard cells (hereinafter simply called cells as appropriate) and at least some of the standard cells include fin field effect transistors (FETs).

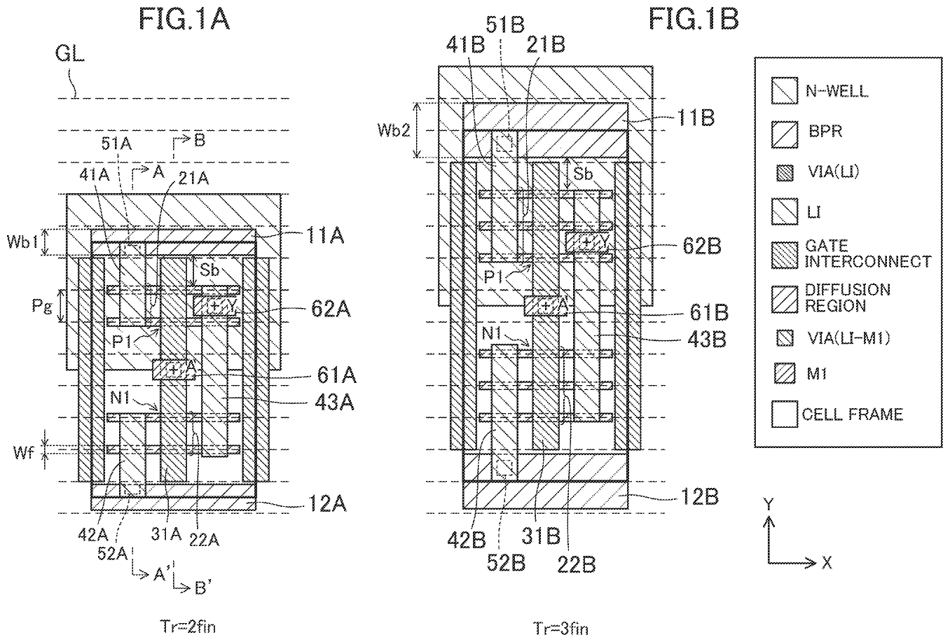

In the present disclosure, “VDD” and “VSS” refer to the power supply voltages or the power supplies themselves. Also, hereinafter, in the plan views such as FIGS. 1A-1B, the horizontal direction in the figure is called an X direction (corresponding to the first direction), the vertical direction in the figure is called a Y direction (corresponding to the second direction), and the direction perpendicular to the substrate plane is called a Z direction.

### First Embodiment

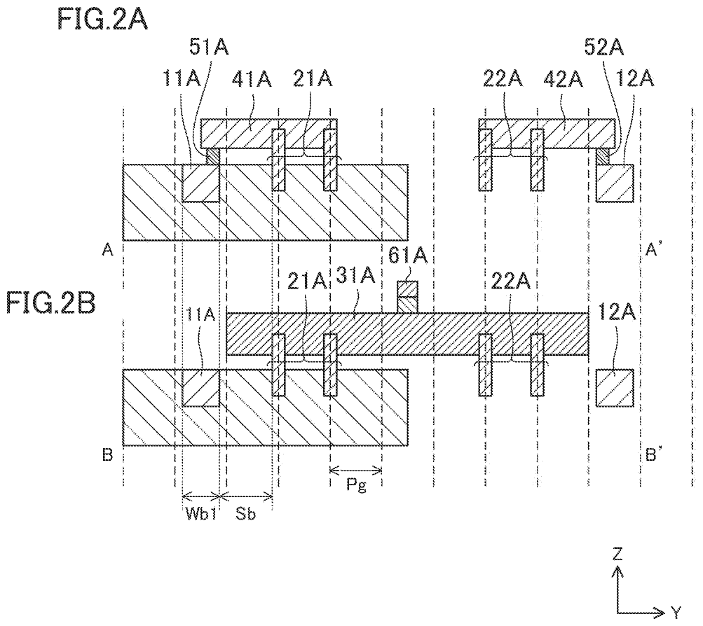

FIGS. 1A-1B are plan views showing layout structure examples of standard cells constituting a semiconductor integrated circuit device according to this embodiment. The standard cells of FIGS. 1A and 1B are both inverter cells. FIGS. 2A-2B are views showing cross-sectional structures of the cell shown in FIG. 1A, where FIG. 2A is a cross-sectional view taken along line A-A′ in FIG. 1A and FIG. 2B is a cross-sectional view taken along line B-B′ in FIG. 1A.

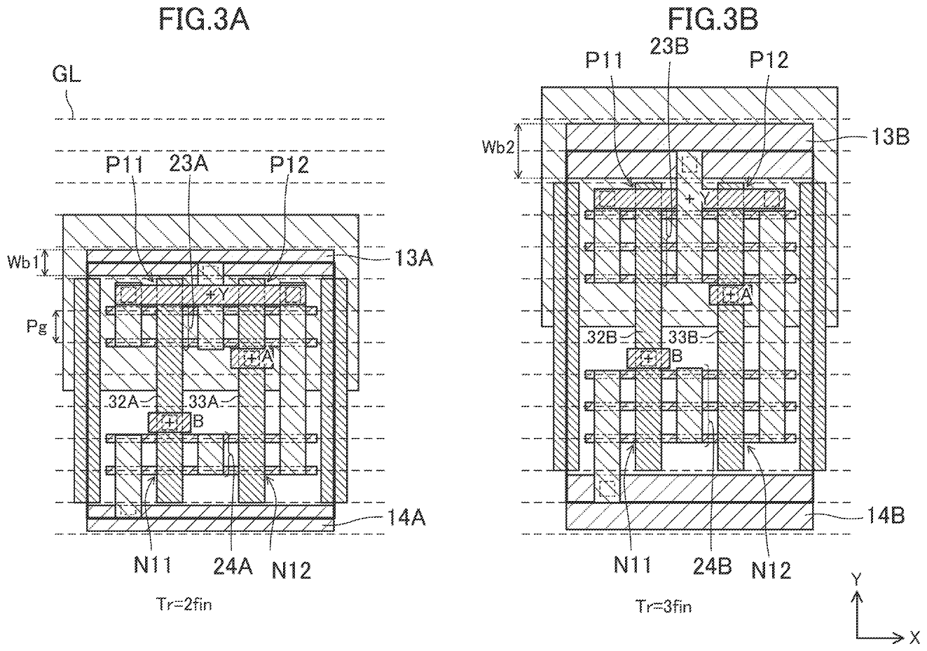

FIGS. 3A-3B are plan views showing layout structure examples of other standard cells constituting the semiconductor integrated circuit device according to this embodiment. The standard cells of FIGS. 3A and 3B are both 2-input NAND cells.

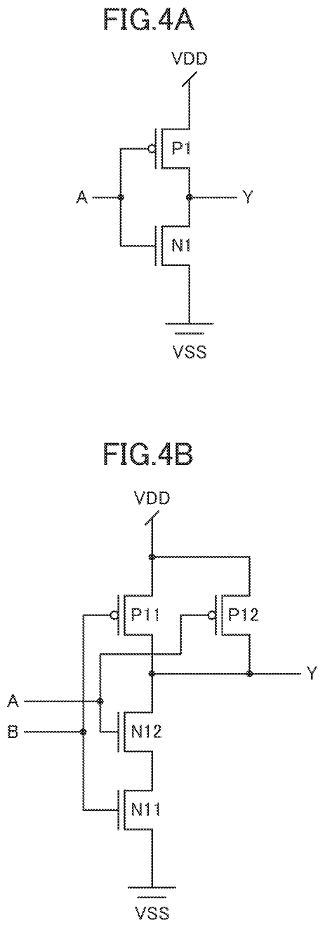

FIGS. 4A-4B show circuit diagrams of cells, where FIG. 4A is a circuit diagram of the inverter cells shown in FIGS. 1A-1B and FIG. 4B is a circuit diagram of the 2-input NAND cells shown in FIGS. 3A-3B.

The inverter cells of FIGS. 1A-1B and the 2-input NAND cells of FIGS. 3A-3B have fin FETs, and a plurality of fins constituting each fin FET extend in the X direction. The plurality of fins are the same in width, i.e., size in the Y direction (denoted by Wf), and are placed on virtual grid lines GL (indicated by the fine broken lines) equally spaced in the Y direction. The pitch of the virtual grid lines GL is Pg. That is, the plurality of fins are placed at a pitch of Pg.

In the inverter cell of FIG. 1A and the 2-input NAND cell of FIG. 3A, the number of fins constituting each fin FET is two and the cell height is Pg×8. In the inverter cell of FIG. 1B and the 2-input NAND cell of FIG. 3B, the number of fins constituting each fin FET is three and the cell height is Pg×11. The drive capability of a fin FET changes with the number of fins constituting the fin FET.

The layout structures of the inverter cells shown in FIGS. 1A-1B and 2A-2B will be described.

In the inverter cell of FIG. 1A, power lines 11A and 12A extending in the X direction are provided along both ends of the cell in the Y direction. The power lines 11A and 12A are both buried power rails (BPR) formed in a buried interconnect layer. The power line 11A supplies the power supply voltage VDD and the power line 12A supplies the power supply voltage VSS. The center position of each of the power lines 11A and 12A in the Y direction agrees with the center between adjacent virtual grid lines GL. The width, i.e., the size in the Y direction of the power lines 11A and 12A is denoted by Wb1.

Two fins 21A extending in the X direction are provided in a p-type transistor region on an N-well, and two fins 22A extending in the X direction are provided in an n-type transistor region on a P-substrate. A gate interconnect 31A extends in the Y direction over the p-type transistor region and the n-type transistor region. As shown in FIG. 2B, the gate interconnect 31A is formed to surround each of the fins 21A and 22A on three sides. The two fins 21A and the gate interconnect 31A constitute a fin FET P1, and the two fins 22A and the gate interconnect 31A constitute a fin FET N1. Note that, from a manufacturing viewpoint, it is necessary to secure a distance Sb between a buried power line and a fin closest to this power line.

A local interconnect 41A extending in the Y direction is provided on left end portions of the fins 21A in the figure. The left end portions of the fins 21A are connected to the power line 11A through the local interconnect 41A and a via 51A. A local interconnect 42A extending in the Y direction is provided on left end portions of the fins 22A in the figure. The left end portions of the fins 22A are connected to the power line 12A through the local interconnect 42A and a via 52A. A local interconnect 43A extending in the Y direction is provided on right end portions of the fins 21A and 22A in the figure. The right end portions of the fins 21A and 22A are mutually connected through the local interconnect 43A.

A metal interconnect 61A into which an input A is given is connected to the gate interconnect 31A through a via. A metal interconnect 62A from which an output Y is output is connected to the local interconnect 43A through a via.

The inverter cell of FIG. 1B has a layout structure similar to the inverter cell of FIG. 1A except that each fin FET is constituted by three fins.

In the inverter cell of FIG. 1B, power lines 11B and 12B extending in the X direction are provided along both ends of the cell in the Y direction. The power lines 11B and 12B are both buried power rails (BPR) formed in a buried interconnect layer. The power line 11B supplies the power supply voltage VDD and the power line 12B supplies the power supply voltage VSS. The center position of each of the power lines 11B and 12B in the Y direction agrees with a virtual grid line GL. The width, i.e., the size in the Y direction of the power lines 11B and 12B is denoted by Wb2. Note that Wb2>Wb1.

Three fins 21B extending in the X direction are provided in a p-type transistor region on an N-well, and three fins 22B extending in the X direction are provided in an n-type transistor region on a P-substrate. A gate interconnect 31B extends in the Y direction over the p-type transistor region and the n-type transistor region. The gate interconnect 31B is formed to surround each of the fins 21B and 22B on three sides. The three fins 21B and the gate interconnect 31B constitute a fin FET P1, and the three fins 22B and the gate interconnect 31B constitute a fin FET N1.

A local interconnect 41B extending in the Y direction is provided on left end portions of the fins 21B in the figure. The left end portions of the fins 21B are connected to the power line 11B through the local interconnect 41B and a via 51B. A local interconnect 42B extending in the Y direction is provided on left end portions of the fins 22B in the figure. The left end portions of the fins 22B are connected to the power line 12B through the local interconnect 42B and a via 52B. A local interconnect 43B extending in the Y direction is provided on right end portions of the fins 21B and 22B in the figure. The right end portions of the fins 21B and 22B are mutually connected through the local interconnect 43B.

A metal interconnect 61B into which an input A is given is connected to the gate interconnect 31B through a via. A metal interconnect 62B from which an output Y is output is connected to the local interconnect 43B through a via.

The layout structures of the 2-input NAND cells shown in FIGS. 3A-3B will be described. Note that description of configurations that can be known by analogy from the layout structures of the inverter cells shown in FIGS. 1A-1B and 2A-2B is omitted in some cases.

In the 2-input NAND cell of FIG. 3A, power lines 13A and 14A extending in the X direction are provided along both ends of the cell in the Y direction. The power lines 13A and 14A are both buried power rails (BPR) formed in a buried interconnect layer. The power line 13A supplies the power supply voltage VDD and the power line 14A supplies the power supply voltage VSS. The center position of each of the power lines 13A and 14A in the Y direction agrees with the center between adjacent virtual grid lines GL. The width, i.e., the size in the Y direction of the power lines 13A and 14A is denoted by Wb1.

Two fins 23A extending in the X direction are provided in a p-type transistor region on an N-well, and two fins 24A extending in the X direction are provided in an n-type transistor region on a P-substrate. Gate interconnects 32A and 33A extend in the Y direction over the p-type transistor region and the n-type transistor region. The two fins 23A and each of the gate interconnects 32A and 33A constitute each of fin FETs P11 and P12. The two fins 24A and each of the gate interconnects 32A and 33A constitute each of fin FETs N11 and N12.

The 2-input NAND cell of FIG. 3B has a layout structure similar to the 2-input NAND cell of FIG. 3A except that each fin FET is constituted by three fins.

In the 2-input NAND cell of FIG. 3B, power lines 13B and 14B extending in the X direction are provided along both ends of the cell in the Y direction. The power lines 13B and 14B are both buried power rails (BPR) formed in a buried interconnect layer. The power line 13B supplies the power supply voltage VDD and the power line 14B supplies the power supply voltage VSS. The center position of each of the power lines 13B and 14B in the Y direction agrees with a virtual grid line GL. The width, i.e., the size in the Y direction of the power lines 13B and 14B is denoted by Wb2. Note that Wb2>Wb1.

Three fins 23B extending in the X direction are provided in a p-type transistor region on an N-well, and three fins 24B extending in the X direction are provided in an n-type transistor region on a P-substrate. Gate interconnects 32B and 33B extend in the Y direction over the p-type transistor region and the n-type transistor region. The three fins 23B and each of the gate interconnects 32B and 33B constitute each of fin FETs P11 and P12. The three fins 24B and each of the gate interconnects 32B and 33B constitute each of fin FETs N11 and N12.

The inverter cell of FIG. 1A and the 2-input NAND cell of FIG. 3A constitute a single circuit block together with other cells having the same cell height (=Pg×8). In this circuit block, such cells are lined up in the X direction, forming a cell row, in which power lines supplying the power supply voltage VDD such as the power lines 11A and 13A are linked together, and power lines supplying the power supply voltage VSS such as the power lines 12A and 14A are linked together. Such cell rows are arranged in the Y direction, with every other cell row being inverted in the Y direction. With this placement, each cell row shares the power lines with its adjacent cell rows in the Y direction.

Similarly, the inverter cell of FIG. 1B and the 2-input NAND cell of FIG. 3B constitute a single circuit block together with other cells having the same cell height (=Pg×11). In this circuit block, such cells are lined up in the X direction, forming a cell row, in which power lines supplying the power supply voltage VDD such as the power lines 11B and 13B are linked together, and power lines supplying the power supply voltage VSS such as the power lines 12B and 14B are linked together. Such cell rows are arranged in the Y direction, with every other cell row being inverted in the Y direction. With this placement, each cell row shares the power lines with its adjacent cell rows in the Y direction.

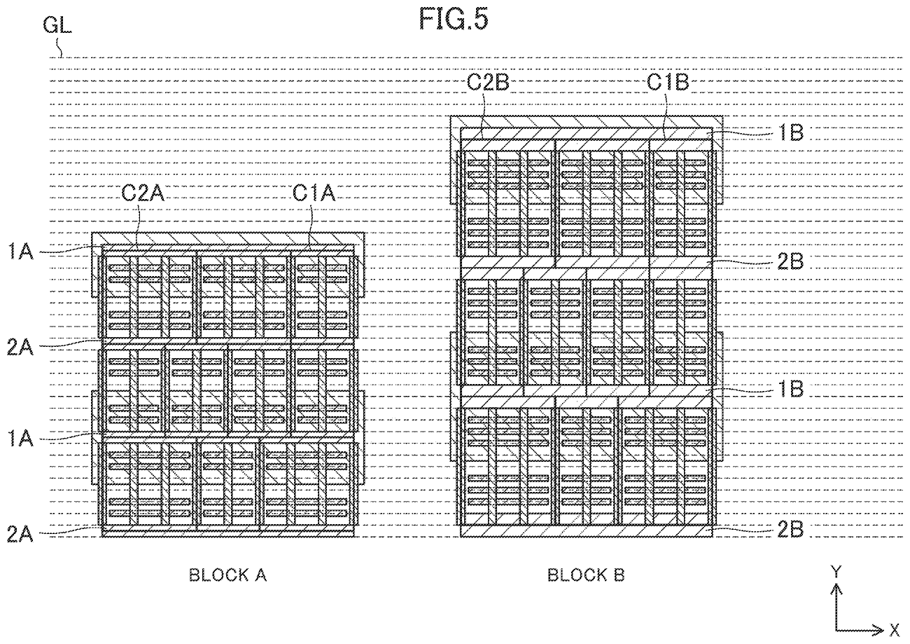

FIG. 5 shows a configuration example of circuit blocks of the semiconductor integrated circuit device according to this embodiment. Note that, in FIG. 5, illustration of components located above the fins and the gate interconnects is omitted. In FIG. 5, a block A is constituted by cells having a cell height of Pg×8, and a block B is constituted by cells having a cell height of Pg×11. The blocks A and B have three cell rows each and share the virtual grid lines GL.

In the block A, a cell C1A is the inverter cell of FIG. 1A and a cell C2A is the 2-input NAND cell of FIG. 3A. In the first row from top in the figure, cells C2A, C2A, and C1A are placed in the order from left to right. In the second row, cells C1A, C1A, C1A, and C1A are placed in the order from left to right, and in the third row, cells C2A, C1A, and C2A are placed in the order from left to right. Power supply lines 1A, supplying the power supply voltage VDD, are each formed of a linkage of the power supply lines 11A of the cells C1A and the power supply lines 13A of the cells C2A. Power supply lines 2A, supplying the power supply voltage VSS, are each formed of a linkage of the power supply lines 12A of the cells C1A and the power supply lines 14A of the cells C2A.

In the block B, a cell C1B is the inverter cell of FIG. 1B and a cell C2B is the 2-input NAND cell of FIG. 3B. In the first row from top in the figure, cells C2B, C2B, and C1B are placed in the order from left to right. In the second row, cells C1B, C1B, C1B, and C1B are placed in the order from left to right, and in the third row, cells C2B, CIB, and C2B are placed in the order from left to right. Power supply lines 1B, supplying the power supply voltage VDD, are each formed of a linkage of the power supply lines 11B of the cells C1B and the power supply lines 13B of the cells C2B. Power supply lines 2B, supplying the power supply voltage VSS, are each formed of a linkage of the power supply lines 12B of the cells C1B and the power supply lines 14B of the cells C2B.

In the block A, in any adjacent cells in the Y direction, the distance between the centers of the fins of these cells closest to each other is 3×Pg. Also, the center position of each of the power lines 1A and 2A is at the center between adjacent virtual grid lines GL. It is therefore possible to secure the width Wb1 of the power lines 1A and 2A to a maximum extent. The width Wb1 of the power lines 1A and 2A is expressed by

Wb1=3×Pg−2×Sb−Wf.

In the block B, in any adjacent cells in the Y direction, the distance between the centers of the fins of these cells closest to each other is 4×Pg. Also, the center position of each of the power lines 1B and 2B is on a virtual grid line GL. It is therefore possible to secure the width Wb2 of the power lines 1B and 2B to a maximum extent. The width Wb2 of the power lines 1B and 2B is expressed by

Wb2=4×Pg−2×Sb−Wf.

That is, the width Wb2 of the power lines 1B and 2B is larger than the width Wb1 of the power lines 1A and 2A by Pg.

The cells constituting the block B have a larger number of fins than the cells constituting the block A. Therefore, the cells in the block B operate at a higher speed, but consume larger power, than the cells in the block A. However, since the power lines 1B and 2B are larger in width than the power lines 1A and 2A as described above, a sufficient current can be supplied to the cells in the block B.

Also, vias 51B and 52B for the power lines 11B and 12B of the inverter cell of FIG. 1B are larger in size and smaller in resistance than the vias 51A and 52A for the power lines 11A and 12A of the inverter cell of FIG. 1A. Therefore, the inverter cell of FIG. 1B can achieve a greater current supply capability. In place of increasing the size of vias, the number of vias may be increased. For example, in the inverter cell of FIG. 1B, two vias may be formed for each of the power lines 11B and 12B.

In the layout of FIG. 5, virtual grid lines GL for placement of fins are shared by the blocks A and B, and cells are placed so that fins included in the blocks A and B be located on the virtual grid lines GL. With this, fins are regularly placed over the entire layout. It is therefore possible to improve the ease of manufacture, minimize manufacturing variations, and improve the yield, of the semiconductor integrated circuit device.

As described above, in the semiconductor integrated circuit device according to this embodiment, a plurality of fins constituting a fin FET extend in the X direction and are placed on virtual grid lines GL equally spaced in the Y direction. Standard cells include buried power lines: a standard cell larger in size in the Y direction includes a buried power line larger in size in the Y direction. With this, a sufficient current supply capability for fin FETs can be obtained. Also, the center position of each of the buried power lines of the standard cells in the Y direction is on a virtual grid line GL or at the center position between adjacent virtual grid lines GL. With this, buried power lines having a sufficient line width can be laid without blocking regular placement of fin FETs.

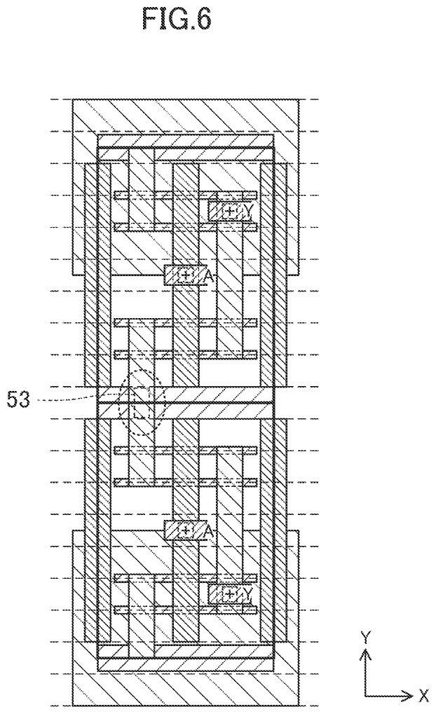

FIG. 6 is a partial enlarged view of the cells C1A on the right end in the first and second rows in the block A in FIG. 5, showing a layout structure of two inverter cells of FIG. 1A placed adjacently in the Y direction. In FIG. 6, in a portion (shown by the broken line) where the vias 52A of the inverter cells of FIG. 1A are be placed adjacently, a via 53 larger than the via 52A is placed.

(Alteration)

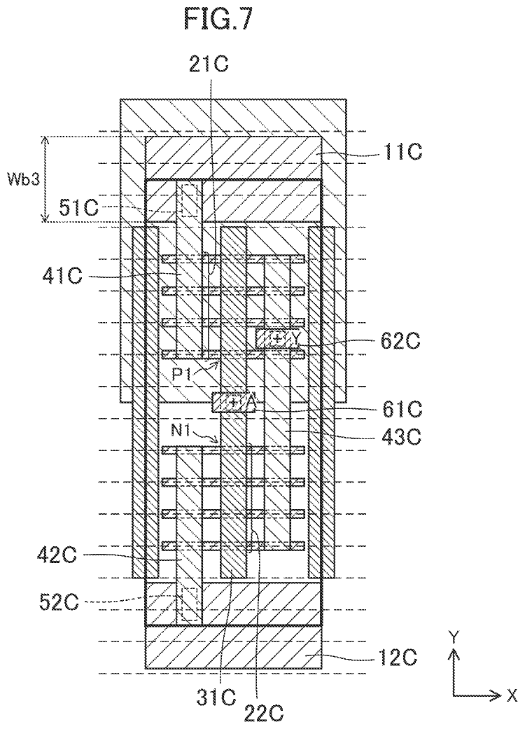

FIG. 7 shows a layout structure of another inverter cell. In the inverter cell of FIG. 7, the number of fins constituting each fin FET is four and the cell height is Pg×14. The other configuration is similar to that of the inverter cells of FIGS. 1A-1B.

In the inverter cell of FIG. 7, power lines 11C and 12C extending in the X direction are provided along both ends of the cell in the Y direction. The power lines 11C and 12C are both buried power rails (BPR) formed in a buried interconnect layer. The power line 11C supplies the power supply voltage VDD and the power line 12C supplies the power supply voltage VSS. The center position of each of the power lines 11C and 12C in the Y direction agrees with the center between adjacent virtual grid lines GL. The width, i.e., the size in the Y direction of the power lines 11C and 12C is denoted by Wb3. Note that Wb3>Wb2.

Four fins 21C extending in the X direction are provided in a p-type transistor region on an N-well, and four fins 22C extending in the X direction are provided in an n-type transistor region on a P-substrate. A gate interconnect 31C extends in the Y direction over the p-type transistor region and the n-type transistor region. The gate interconnect 31C is formed to surround each of the fins 21C and 22C on three sides. The four fins 21C and the gate interconnect 31C constitute a fin FET P1, and the four fins 22C and the gate interconnect 31C constitute a fin FET N1.

A local interconnect 41C extending in the Y direction is provided on left end portions of the fins 21C in the figure. The left end portions of the fins 21C are connected to the power line 11C through the local interconnect 41C and a via 51C. A local interconnect 42C extending in the Y direction is provided on left end portions of the fins 22C in the figure. The left end portions of the fins 22C are connected to the power line 12C through the local interconnect 42C and a via 52C. A local interconnect 43C extending in the Y direction is provided on right end portions of the fins 21C and 22C in the figure. The right end portions of the fins 21C and 22C are mutually connected through the local interconnect 43C.

A metal interconnect 61C into which an input A is given is connected to the gate interconnect 31C through a via. A metal interconnect 62C from which an output Y is output is connected to the local interconnect 43C through a via.

The inverter cell of FIG. 7 constitutes a single circuit block together with other cells having the same cell height (=Pg×14). This block may also be placed on common virtual grid lines GL together with the blocks A and B shown in FIG. 5, for example.

The width Wb3 of the power lines 11C and 12C is expressed by

Wb3=5×Pg−2×Sb−Wf.

That is, Wb3 is larger than Wb2 by Pg.

Also, vias 51C and 52C for the power lines 11C and 12C are even larger in size than the vias 51B and 52B for the power lines 11B and 12B of the inverter cell of FIG. 1B.

Therefore, the inverter cell of FIG. 7 can achieve an even greater current supply capability. In place of increasing the size of vias, the number of vias may be increased. For example, if two vias are formed for each of the power lines 11B and 12B in the inverter cell of FIG. 1B, three vias may be formed for each of the power lines 11C and 12C in the inverter cell of FIG. 7.

While the semiconductor integrated circuit device was illustrated as including standard cells having fin FETs in the above description, the transistors of the standard cells are not limited to fin FETs. For example, the present disclosure is also applicable to a semiconductor integrated circuit device including standard cells having nanosheet FETs.

According to the present disclosure, in a semiconductor integrated circuit device using buried power lines, buried power lines having a sufficient line width are laid without blocking regular placement of fin FETs. The present disclosure is therefore useful for improving the integration degree and performance of system LSI, for example.

1. A semiconductor integrated circuit device comprising a plurality of standard cells each having a fin field effect transistor (FET),
wherein
a plurality of fins constituting the fin FET extend in a first direction and placed on ones of virtual grid lines equally spaced in a second direction vertical to the first direction,
the plurality of standard cells include a first standard cell and a second standard cell larger in size in the second direction than the first standard cell,
the first standard cell includes a first buried power line extending in the first direction,
the second standard cell includes a second buried power line extending in the first direction, the second buried power line being larger in size in the second direction than the first buried power line, and
a center position of each of the first and second buried power lines in the second direction is on one of the virtual grid lines or at a center position between adjacent ones of the virtual grid lines.

2. The semiconductor integrated circuit device of claim 1, wherein
the first standard cell includes a first fin FET having N (N is an integer equal to or greater than 1) fin or fins, and
the second standard cell includes a second fin FET having M (M is an integer greater than N) fins.

3. The semiconductor integrated circuit device of claim 1, wherein
the first standard cell includes a first local interconnect extending in the second direction and connected to the first buried power line through a first via,
the second standard cell includes a second local interconnect extending in the second direction and connected to the second buried power line through a second via, and
the second via is larger in size than the first via, or the number of second vias is larger than the number of first vias.

4. The semiconductor integrated circuit device of claim 1, wherein
the first and second standard cells achieve the same circuit function.

5. The semiconductor integrated circuit device of claim 1, wherein
the plurality of standard cells include a third standard cell larger in size in the second direction than the second standard cell, and
the third standard cell includes a third buried power line extending in the first direction, the third buried power line being larger in size in the second direction than the second buried power line.

6. The semiconductor integrated circuit device of claim 5, wherein
the first standard cell includes a first fin FET having N (N is an integer equal to or greater than 1) fin or fins,
the second standard cell includes a second fin FET having M (M is an integer greater than N) fins, and
the third standard cell includes a third fin FET having L (L is an integer greater than M) fins.

7. The semiconductor integrated circuit device of claim 5, wherein
the first standard cell includes a first local interconnect extending in the second direction and connected to the first buried power line through a first via,
the second standard cell includes a second local interconnect extending in the second direction and connected to the second buried power line through a second via,
the third standard cell includes a third local interconnect extending in the second direction and connected to the third buried power line through a third via,
the second via is larger in size than the first via, or the number of second vias is larger than the number of first vias, and
the third via is larger in size than the second via, or the number of third vias is larger than the number of second vias.
